(19) United States
(12) Patent Application Publication
(10) Pub. No.: US 2011/0273847 A1
(43) Pub. Date: Nov. 10, 2011

(54) ALLOY COMPOSITIONS AND TECHNIQUES FOR REDUCING INTERMETALLIC COMPOUND THICKNESSES AND OXIDATION OF METALS AND ALLOYS

(76) Inventors: Hong-Sik Hwang, Clinton, NY (US); Ning-Cheng Lee, New Hartford, NY (US)

(21) Appl. No.: 13/099,135

(22) Filed: May 2, 2011

Related U.S. Application Data
(62) Division of application No. 11/745,784, filed on May 8, 2007, now abandoned.
(60) Provisional application No. 60/746,710, filed on May 8, 2006.

(51) Int. Cl. H05K 7/20; H05K 7/00

(52) U.S. Cl. 361/720; 361/679.01; 361/704

(57) ABSTRACT

Alloy compositions and techniques for reducing IMC thickness and oxidation of metals and alloys are disclosed. In one particular exemplary embodiment, the alloy compositions may be realized as a composition of alloy or mixture consisting essentially of from about 90% to about 99.999% by weight indium and from about 0.001% to about 10% by weight germanium and unavoidable impurities. In another particular exemplary embodiment, the alloy compositions may be realized as a composition of alloy consisting essentially of from about 90% to about 99.999% by weight gallium and from about 0.001% to about 10% by weight germanium and unavoidable impurities.

### CROSS-REFERENCE TO RELATED APPLICATIONS

This patent application claims priority to U.S. Provisional Patent Application No. 60/746,710, filed May 8, 2006, which is hereby incorporated by reference herein in its entirety.

### FIELD OF THE DISCLOSURE

The present disclosure relates generally to electrical and thermal conduction and, more particularly, alloy compositions and techniques for reducing intermetallic compound (IMC) thickness and oxidation of metals and alloys.

### BACKGROUND OF THE DISCLOSURE

When working with electronic devices, solder joints should give sufficient reliability during service. Solder joint reliability largely relies on IMC growth that is caused by time and heat generated during service. In general, thicker IMC causes reliability problems due to brittleness of IMC, formation of Kirkendall voiding, and/or depletion of metal layer(s) upon which solder is applied, especially, when the metal layer(s) is thin such as in under bump metallization (UBM).

On the other hand, the development of new thermal interface materials (TIM's) is required to address increases in device processing speeds and heat generation. Thermal solders are very attractive because they have high thermal conductivities. Soldered TIM's have similar problems as solder joints in that IMC growth causing reliability problems may occur as devices run at elevated temperatures.

Low melting point metals, including liquid metals, are also useful as thermally conductive materials due to good conformity of the low melting point metals with contacting surfaces, good metallic phase continuity of the low melting point metals at service temperatures, and the formation of good thermally conductive pathways or chains of the low melting point metals at service temperatures. The use of low melting point metals, however, is limited in some specific applications due to rapid oxidation and high reactivity.

New types of TIM's, such as polymer solder hybrids (PSH), have been recently introduced wherein a polymer matrix acts as an adhesive on a surface of a die or package and solder filler serves as a thermal conductor. Several possible applications of low melting point metals have been attempted as thermal conductive fillers or as a part of conductive fillers in PSH's. However, low melting point metals, including liquid metals, oxidize very quickly and form loosely aggregated solids, which easily delaminate at interfaces. As a result, using this type of TIM is very challenging.

In view of the foregoing, it would be desirable to provide techniques for reducing IMC thickness and oxidation of metals and alloys which overcome the above-described inadequacies and shortcomings.

### SUMMARY OF THE DISCLOSURE

Alloy compositions and techniques for reducing IMC thickness and oxidation of metals and alloys are disclosed. In one particular exemplary embodiment, the alloy compositions may be realized as a composition of alloy or mixture consisting essentially of from about 90% to about 99.999% by weight indium and from about 0.001% to about 10% by weight germanium and unavoidable impurities. In another particular exemplary embodiment, the alloy compositions may be realized as a composition of alloy or mixture consisting essentially of from about 90% to about 99.999% by weight indium and from about 0.001% to about 10% by weight of one or more of germanium, manganese, phosphorus, and titanium. In yet another particular exemplary embodiment, the alloy compositions may be realized as a composition of alloy consisting essentially of from about 90% to about 99.999% by weight gallium and from about 0.001% to about 10% by weight germanium and unavoidable impurities. In still another particular exemplary embodiment, the alloy compositions may be realized as a composition of alloy consisting essentially of from about 90% to about 99.999% by weight gallium and from about 0.001% to about 10% by weight of one or more of germanium, manganese, phosphorus, and titanium. In still yet another particular exemplary embodiment, the alloy compositions may be realized as a composition of alloy consisting essentially of gallium-indium alloy, gallium-indium-tin alloy, gallium-indium-tin-zinc alloy, cadmium, cadmium alloys, indium-lead alloy, indium-lead-silver alloy, mercury, mercury alloys, bismuth-tin alloy, indium-tin-bismuth alloy, and mixtures thereof containing from about 0.001% to about 10% by weight of one or more of germanium, manganese, phosphorus, and titanium and unavoidable impurities.

The alloy compositions may take the form of a metallurgical interconnect material, a thermal interface material, a thermally conductive filler, or a thermally conductive medium. The thermal interface material may comprise one or more of a phase change material, a thermally conductive gel, a thermally conductive tape, and a thermal grease.

In one particular exemplary embodiment, the techniques may be realized as a method of incorporating from about 0.001% to about 10% by weight of one or more dopants including one or more of germanium, manganese, phosphorus, and titanium in a metal or metal alloy comprising from about 90% to about 99.999% by weight gallium or indium, wherein the method comprises mixing the one or more dopants into the metal or metal alloy as a solution with heat. The mixture may be quickly cooled to get finer dopant or intermetallic particles that diffuse faster than larger particles.

In another particular exemplary embodiment, the techniques may be realized as a method of incorporating from about 0.001% to about 10% by weight of one or more dopants including one or more of germanium, manganese, phosphorus, and titanium in a metal or metal alloy comprising from about 90% to about 99.999% by weight gallium or indium, wherein the method comprises mixing the one or more dopants as particulates into a molten metal or metal alloy, and cooling the molten metal or metal alloy with the one or more dopant particulates to form a metal or metal alloy composite.

In another particular exemplary embodiment, the techniques may be realized as a method of incorporating from about 0.001% to about 10% by weight of one or more dopants including one or more of germanium, manganese, phosphorus, and titanium in a metal or metal alloy comprising from about 90% to about 99.999% by weight gallium or indium, wherein the method comprises mixing the one or more dopants into a solid form of the metal or metal alloy by mechanical force.

In another particular exemplary embodiment, the techniques may be realized as a method of incorporating from about 0.001% to about 10% by weight of one or more dopants including one or more of germanium, manganese, phosphorus, and titanium in a metal or metal alloy comprising from about 90% to about 99.999% by weight gallium or indium, wherein the method comprises mixing the one or more dopants as particulates into a metal or metal alloy powder to form a metal or metal alloy powder mixture.

In another particular exemplary embodiment, the techniques may be realized as a method of incorporating from about 0.001% to about 10% by weight of one or more dopants including one or more of germanium, manganese, phosphorus, and titanium in a metal or metal alloy comprising from about 90% to about 99.999% by weight gallium or indium, wherein the method comprises putting the one or more dopants as particulates in an interconnecting substrate with the metal or metal alloy, wherein the interconnecting substrate may include at least one of a pad on circuit board, a heat spreader, a heat sink, and a back side of component.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 is a table of IMC thickness and Nickel (Ni) layer consumption of aged pure Indium (In) and 2% Germanium (Ge)/Indium (In) samples in accordance with an embodiment of the present disclosure.

FIG. 2 shows a scanning electron microscopy (SEM) picture, magnified ×1000, of a pure Indium (In) sample on a Nickel (Ni)/Gold (Au) substrate aged for 1000 hrs at 150° C. in accordance with an embodiment of the present disclosure.

FIG. 3 shows a scanning electron microscopy (SEM) picture, magnified ×1000, of a 2% Germanium (Ge)/Indium (In) sample on a Nickel (Ni)/Gold (Au) substrate aged for 1000 hrs at 150° C. in accordance with an embodiment of the present disclosure.

FIG. 4 shows a scanning electron microscopy (SEM) picture, magnified ×3000, of a 2% Germanium (Ge)/Indium (In) sample on a Nickel (Ni)/Gold (Au) substrate aged for 1000 hrs at 150° C. in accordance with an embodiment of the present disclosure.

FIG. 5 is a table of IMC compositions of aged pure Indium (In) and 2% Germanium (Ge)/Indium (In) samples in accordance with an embodiment of the present disclosure.

FIG. 6 shows a graph of oxide formed in a 85° C./85% relative humidity chamber for pure Gallium (Ga) and 0.05% and 0.1% Germanium (Ge)-doped Gallium (Ga) in accordance with an embodiment of the present disclosure.

FIG. 7 shows a graph of oxide formed in a 85° C./85% relative humidity chamber for 0.5%, 1%, 2%, and 5% Germanium (Ge)-doped Gallium (Ga) in accordance with an embodiment of the present disclosure.

FIG. 8 shows a graph of oxide formed in a 85° C./85% relative humidity chamber for 0.0001% and 0.0005% Germanium (Ge)-doped Gallium (Ga) in accordance with an embodiment of the present disclosure.

FIG. 9 shows a graph of oxide formed in a 85° C./85% relative humidity chamber for Gallium (Ga)/Indium (In) alloys with and without 0.5% Germanium (Ge) in accordance with an embodiment of the present disclosure.

FIG. 10 shows a graph of oxide formed in a 85° C./85% relative humidity chamber for Indium (In)/Bismuth (Bi) alloys with and without 0.5% Germanium (Ge) in accordance with an embodiment of the present disclosure.

FIG. 11 shows a graph of oxide formed in a 85° C./85% relative humidity chamber for Gallium (Ga) alloys containing 0.5% Phosphorus (P), 0.5% Titanium (Ti), 0.5% Manganese (Mn), and no dopants in accordance with an embodiment of the present disclosure.

FIG. 12 is a table of relative peak intensity of Germanium (Ge) to Gallium (Ga) with different laser power for 2% Germanium (Ge)/Gallium (Ga) in accordance with an embodiment of the present disclosure.

FIG. 13 shows a graph of ICP-MS spectrum of 2% Germanium (Ge)/Gallium (Ga) for 15% laser power in accordance with an embodiment of the present disclosure.

FIG. 14 shows a graph of ICP-MS spectrum of 2% Germanium (Ge)/Gallium (Ga) for 25% laser power in accordance with an embodiment of the present disclosure.

FIG. 15 shows a mounting configuration wherein a metallurgical bond is formed between a pad of an electronic component and a pad of a substrate through an interconnecting material, such as solder, in accordance with an embodiment of the present disclosure.

FIG. 16 shows an application of a TIM in an electronic assembly in accordance with an embodiment of the present disclosure.

FIG. 17 shows a simplified example of a first TIM in the form of a phase change material, a thermally conductive gel, a thermally conductive tape, or a thermal grease that comprises a polymeric matrix filled with a thermally conductive filler between an IHS and an electronic component in accordance with an embodiment of the present disclosure.

FIG. 18 shows an example wherein a first TIM is a PSH where a thermally conductive filler stays as a liquid at service temperature and a polymeric matrix gives mechanical adhesion between an IHS and an electronic component in accordance with an embodiment of the present disclosure.

FIG. 19 shows an example wherein TIM material may be placed directly between an IHS and an electronic component without a polymeric matrix in accordance with an embodiment of the present disclosure.

### DETAILED DESCRIPTION OF EXEMPLARY EMBODIMENTS

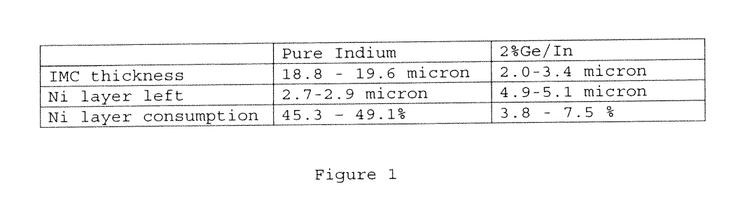

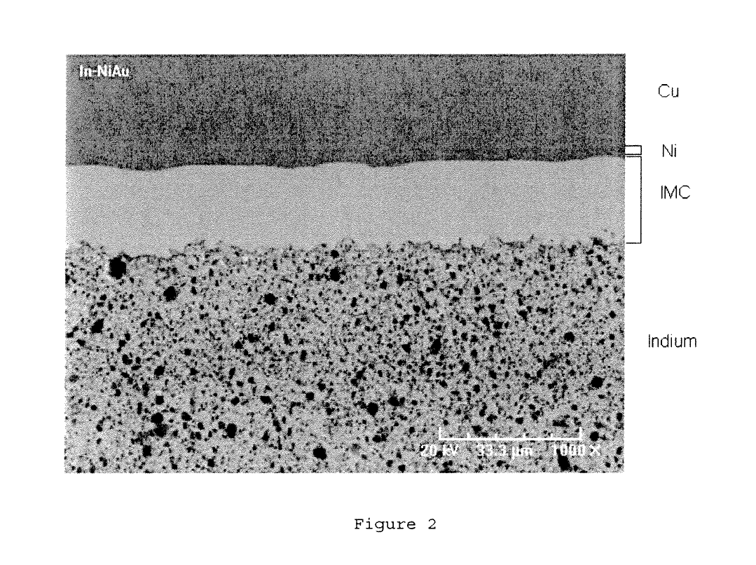

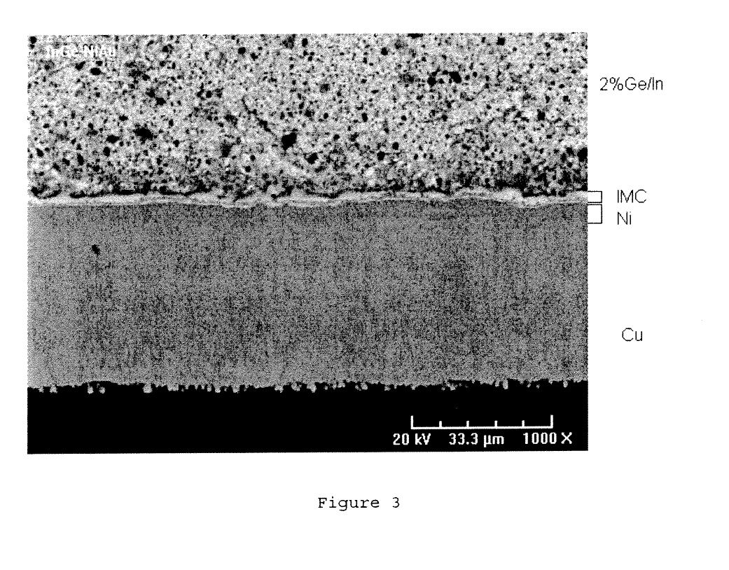

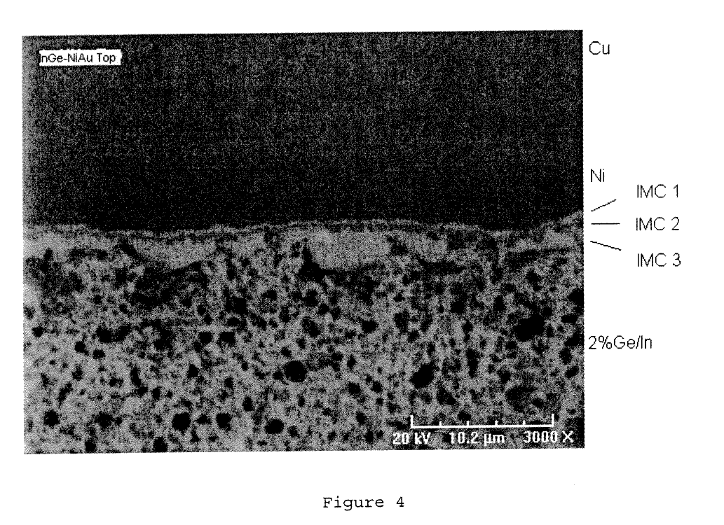

Alloy compositions and techniques for reducing IMC thickness and oxidation of metals and alloys in accordance with embodiments of the present disclosure are described. Such alloy compositions and techniques were discovered through experimental testing. For example, in order to solve problems of solder joint reliability, an IMC growth test was used to reveal a technique for preventing IMC growth of interconnect material such as solder and TIM in accordance with an embodiment of the present disclosure. That is, significant, unprecedented effects were observed when IMC growths of 2% (wt) Germanium (Ge)/Indium (In) and pure Indium (In) on an electrolytic Nickel (Ni)/Gold (Au) substrate after aging in a 150° C. oven for 1000 hours. IMC thickness and Nickel (Ni) layer consumption of samples were measured after aging the samples. As shown in the table of FIG. 1, total IMC thickness of pure Indium (In) was about 18.8-19.6 microns while the IMC thickness of 2% Germanium (Ge)/Indium (In) was about 2.0-3.4 microns. The original thickness of Nickel (Ni) layer of the substrate was 5.3 microns and the Nickel (Ni) layer consumption of samples with pure Indium (In) and 2% Germanium (Ge)/Indium (In) were determined as 45.3-49.1% and 3.8-7.5%, respectively. FIGS. 2 and 3 show scanning electron microscopy (SEM) pictures of a pure Indium (In) sample and a 2% Germanium (Ge)/Indium (In) sample, respectively, on an electrolytic Nickel (Ni)/Gold (Au) substrate after aging in a 150° C. oven for 1000 hours. The decrease in IMC in the 2% Germanium (Ge)/Indium (In) sample is readily apparent. When seen at higher magnification, it is also apparent that the INC consists of three layers (see FIG. 4).

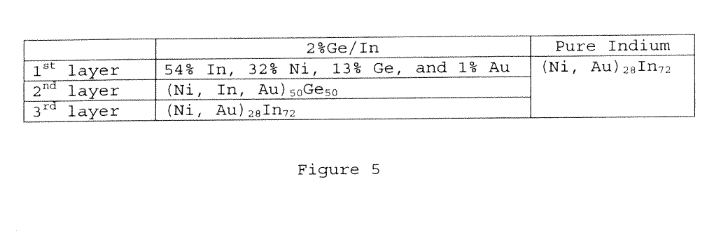

In order to understand the mechanism for thinner INC in germanium-doped indium, energy dispersive spectrometry (EDS) is helpful and thus was performed. The table of FIG. 5 summarizes EDS analysis results for the pure Indium (In) sample and the 2% Germanium (Ge)/Indium (In) sample.

Summarizing, as shown in FIG. 2, only one layer of IMC is found in the pure Indium (In) sample. However, as shown in FIGS. 3 and 4, three layers of IMC are found in the 2% Germanium (Ge)/Indium (In) sample. As shown in the table of FIG. 5, the composition of the IMC in the pure Indium (In) sample was determined to be (Ni, AU)₂₈In₇₂. Meanwhile, the composition of the first IMC layer (i.e., closest to solder) of the 2% Germanium (Ge)/Indium (In) sample was determined to be 54% Indium (In), 32% Nickel (Ni), 13% Germanium (Ge), and 1% Gold (Au). It should be noted, however, that the actual composition of the first IMC layer of the 2% Germanium (Ge)/Indium (In) sample may not be precisely accurate because the first IMC layer of the 2% Germanium (Ge)/Indium (In) sample was thinner than the measurement resolution. Thus, materials in areas other than the first IMC layer of the 2% Germanium (Ge)/Indium (In) sample may be included in the composition of the first IMC layer of the 2% Germanium (Ge)/Indium (In) sample. The second IMC layer of the 2% Germanium (Ge)/Indium (In) sample, however, was thicker than the first IMC layer of the 2% Germanium (Ge)/Indium (In) sample and thus it was possible to determine the exact composition of the second IMC layer of the 2% Germanium (Ge)/Indium (In) sample as (Ni, In, Au)₅₀Ge₅₀. The composition of third IMC layer of the 2% Germanium (Ge)/Indium (In) sample was same as the composition of the INC in the pure Indium (In) sample.

It is believed that Germanium (Ge) reacts with Nickel (Ni) in the early stages of aging to form Germanium (Ge)-rich INC layers and that these Germanium (Ge)-rich INC layers protect the Nickel (Ni) layer from reaction with solder. It is also believed that when a certain INC layer forms a dense and stable layer that can block inter-diffusion between solder and a substrate material, thinner total INC and less consumption of the substrate material such as for UBM is observed. Thus, it is further believed that formation of such a protective IMC layer results in better reliability. From the discussion above, it may be concluded that the thin layer(s) of Germanium (Ge)-rich IMC plays a role as diffusion barrier to slow down solder diffusion to substrate.

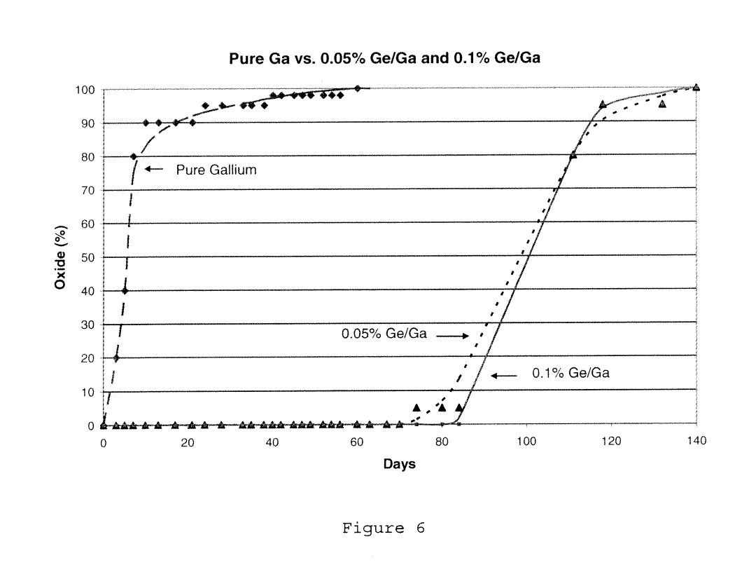

In order to solve problems of oxidation of metals, including low melting temperature metals, an oxidation test was used to reveal a technique for preventing oxidation in accordance with an embodiment of the present disclosure. Indeed, the above-described significant, unprecedented effects of Germanium (Ge) were also observed in low melting temperature metals such as gallium in the oxidation test. That is, samples of low melting temperature metals 99.95% Gallium (Ga)/0.05% Germanium (Ge), 99.9% Gallium (Ga)/0.1% Germanium (Ge), and pure Gallium (Ga) were placed in a 85° C./85% relative humidity chamber. Metal oxide formed on top of the metals in a vial. The amount of oxide was determined by measuring the height of the oxide part (volume) formed on top of the metals. The amount of oxide for the pure Gallium (Ga) sample increased rapidly and showed about 90% oxide in 10 days. In contrast, the samples of Gallium (Ga) containing small amounts of Germanium (Ge) showed much slower oxidation rates. Indeed, the 99.95% Gallium (Ga)/0.05% Germanium (Ge) and 99.9% Gallium (Ga)/0.1% Germanium (Ge) samples didn't show a significant amount of oxide until after 80 days in the 85° C./85% relative humidity chamber (see FIG. 6).

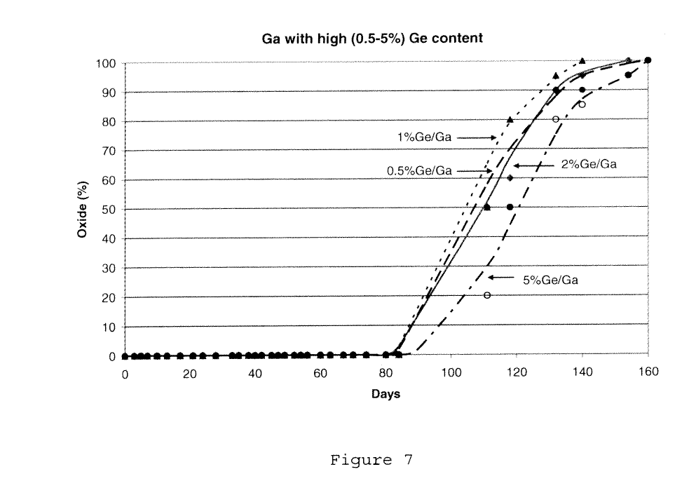

To see if higher concentrations of Germanium (Ge) may give better oxidation properties, samples of Gallium (Ga) containing 0.5, 1, 2, and 5% (wt) Germanium (Ge) were tested. As shown in FIG. 7, there is no big improvement by using higher concentrations of Germanium (Ge).

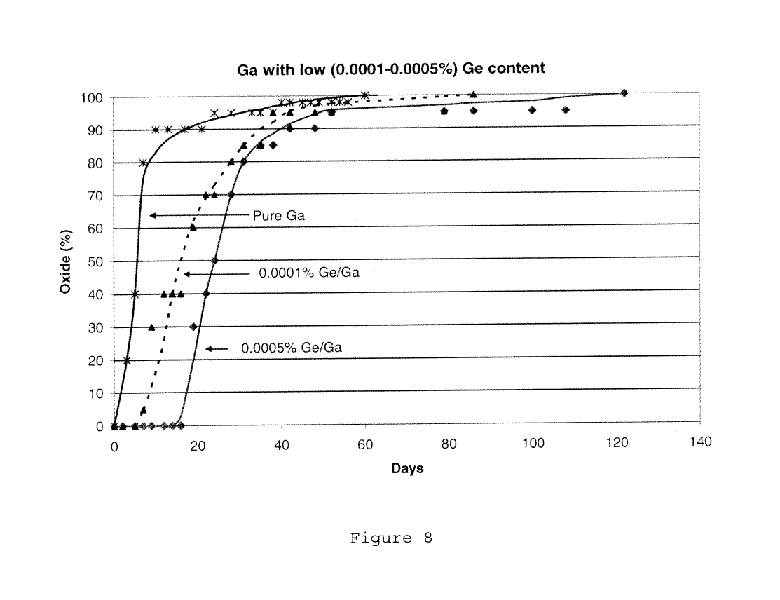

To check for a lower limit of the effective amount of Germanium (Ge), 0.0001% Germanium (Ge)/Gallium (Ga) and 0.0005% Germanium (Ge)/Gallium (Ga) were tested. As shown in FIG. 8, only a slight effect was observed for these alloys.

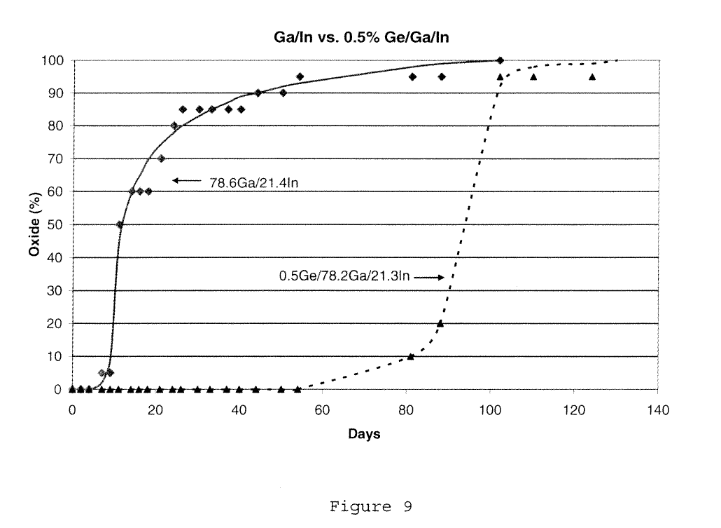

Gallium (Ga)/Indium (In) is a eutectic alloy and thus may also be a good thermal interface material. The anti-oxidation effect of Germanium (Ge) on such an alloy would therefore be of interest in view of the above findings. Therefore, the oxidation rate of a 78.6% Gallium (Ga)/21.4% Indium (In) alloy was compared with a 0.5% Germanium (Ge)/78.2% Gallium (Ga)/21.3% Indium (In) alloy. As shown in FIG. 9, the Germanium (Ge)-containing Gallium (Ga)/Indium (In) alloy showed a much more stable oxidation property.

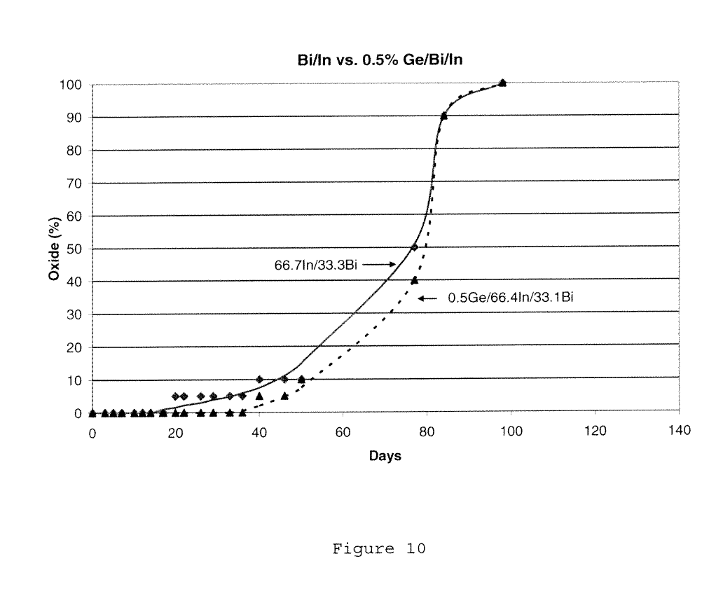

Bismuth (Bi)/Indium (In) is also a eutectic alloy and thus may also be a good thermal interface material. The anti-oxidation effect of Germanium (Ge) on such an alloy would therefore be of interest in view of the above findings. Therefore, the oxidation rate of a 66.7% Indium (In)/33.3% Bismuth (Bi) alloy was compared with a 0.5% Germanium (Ge)/66.4% Indium (In)/33.1% Bismuth (Bi) alloy. As shown in FIG. 10, only a slight anti-oxidation effect was observed for the Germanium (Ge)-containing Indium (In)/Bismuth (Bi) alloy.

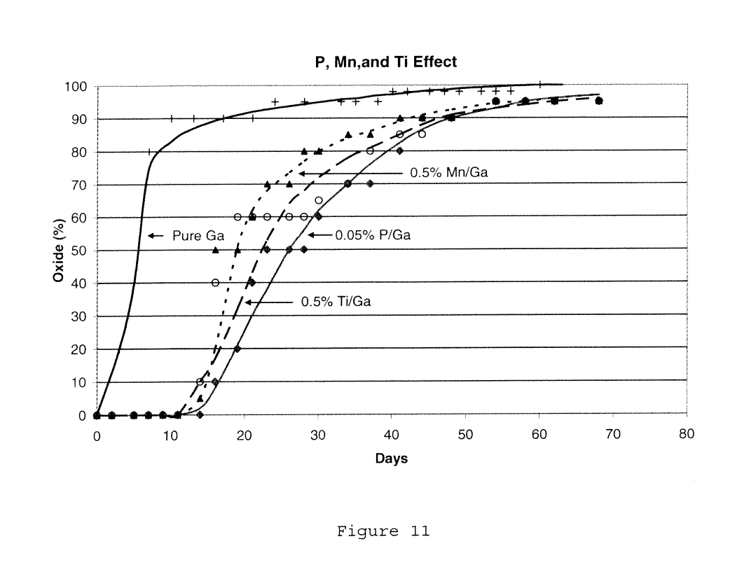

For comparison purposes, the anti-oxidation effect of other dopants on Gallium (Ga) would be of interest in view of the above findings. Therefore, the oxidation rate of 0.5% Phosphorus (P)/Gallium (Ga), 0.5% Titanium (Ti)/Gallium (Ga), and 0.5% Manganese (Mn)/Gallium (Ga) were compared with pure Gallium (Ga). As shown in FIG. 11, some anti-oxidation effect Was observed for the Phosphorus (P), Titanium (Ti), and Manganese (Mn)-doped Gallium (Ga), but not as much as Germanium (Ge)-doped Gallium (Ga).

The mechanism for using Germanium (Ge) to protect Gallium (Ga) from oxidation was investigated. It was assumed that a thin Germanium (Ge)-containing protective layer was formed and that this layer protected further reaction of Gallium (Ga) with oxygen. A laser ablation ICP-MS method was used to verify this mechanism. The laser ablation ICP-MS method is widely used for surface composition analysis. During this method a high energy laser ablates a small area of the surface of a sample. The ablated material is then transferred into an ICP-MS analysis chamber. The higher the laser intensity, the deeper the ablation.

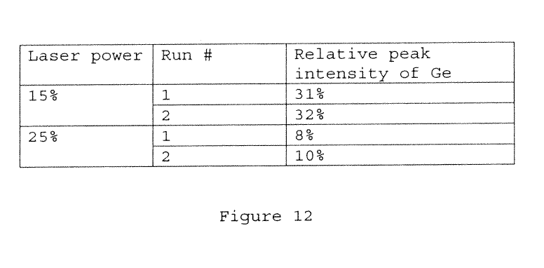

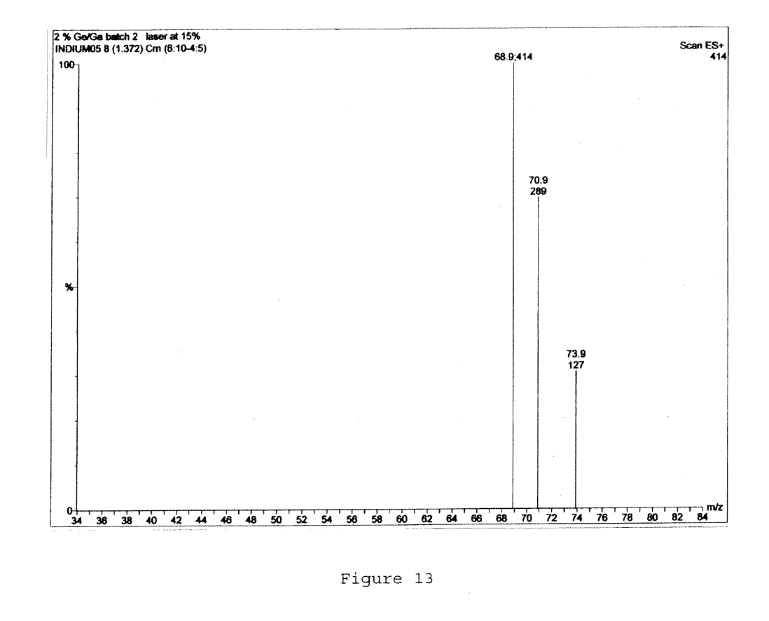

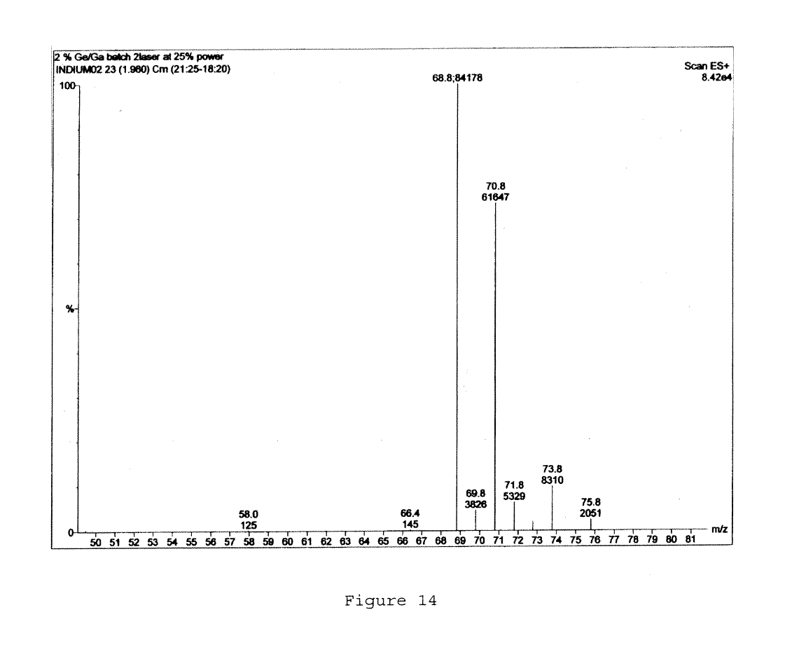

When lower laser power (15%) was used so that the ablation was shallow, the relative intensity of the Germanium (Ge) major peak (68.8-68.9) was 31-32% to the Gallium (Ga) major peak (68.8-68.9) for 2% Germanium (Ge)/Gallium (Ga). When the higher laser power (25%) was used, the relative intensity of Germanium (Ge) was 8-10%. The results give qualitative evidence that the Germanium (Ge) atoms go to the surface to protect the alloy from oxidation. The test has repeated at a different spot of the sample and showed the same result. FIGS. 12-14 show the analysis results.

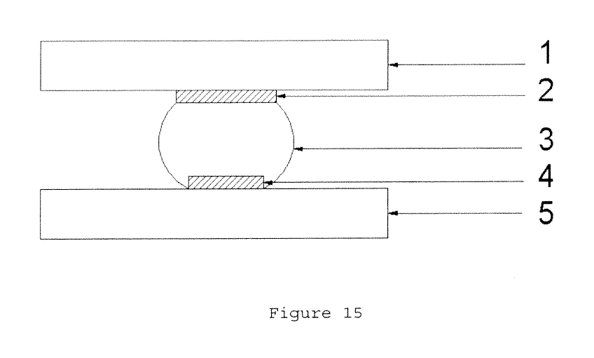

Referring to FIG. 15, there is shown a mounting configuration wherein a metallurgical bond is formed between a pad 2 of an electronic component 1 and a pad 4 of a substrate 5 through an interconnecting material 3, such as solder, in accordance with an embodiment of the present disclosure. IMC layers build up between the solder interconnecting material 3 and the component pad 2 and/or the substrate pad 4. The compositions described herein may reduce IMC growth between the solder interconnecting material 3 and the component pad 2 and/or the substrate pad 4 to increase reliability of the electronic component 1.

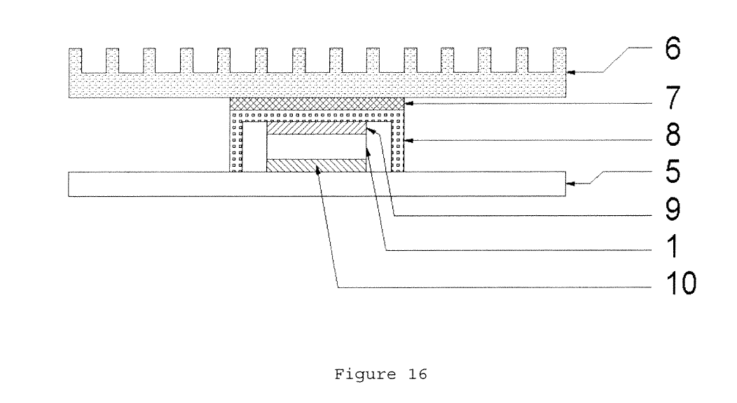

Referring to FIG. 16, there is shown an application of a TIM in an electronic assembly in accordance with an embodiment of the present disclosure. The electronic assembly comprises a substrate 5 connected to an electronic component 1 through interconnecting material 10. An integrated heat spreader (IHS) 8 is attached to a top side of the electronic component 1 using a first TIM 9 to dissipate heat generated from the electronic component 1. The IHS 8 is also connected to a heat sink 6 by a second TIM 7 for further dissipation of heat.

One of the most effective materials for the first TIM 9 and the second TIM 7 is a thermal solder such as indium, indium alloys, gallium-indium alloy, gallium-indium-tin alloy, gallium-indium-tin-zinc alloy, indium-lead alloy, indium-lead-silver alloy, bismuth-tin alloy, and indium-tin-bismuth alloy. The compositions described herein may reduce IMC growth between the electronic component 1 and the IHS 8 and/or between the IHS 8 and the heat sink 6 to increase reliability.

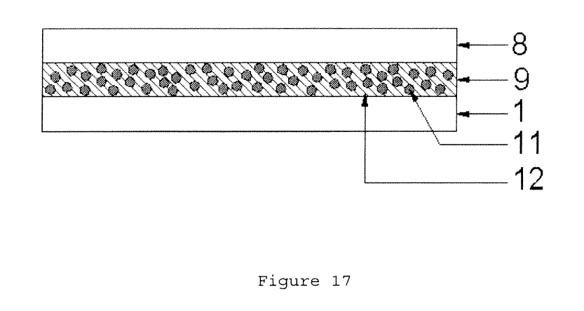

Referring to FIG. 17, there is shown a simplified example of the first TIM 9 in the form of a phase change material, a thermally conductive gel, a thermally conductive tape, or a thermal grease that comprises a polymeric matrix 12 filled with a thermally conductive filler 11 between the IHS 8 and the electronic component 1 in accordance with an embodiment of the present disclosure. The conductive filler 11 may include indium, indium alloys, gallium, gallium-indium alloy, gallium-indium-tin alloy, gallium-indium-tin-zinc alloy, cadmium, cadmium alloys, indium-lead alloy, indium-lead-silver alloy, mercury, mercury alloys, bismuth-tin alloy, and indium-tin-bismuth alloy. The compositions described herein may improve oxidation properties and reduce reactivity of the thermally conductive filler 11.

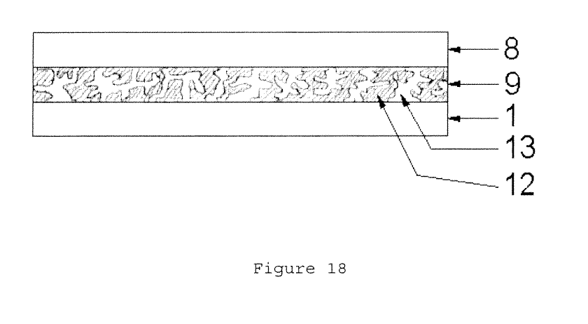

Referring to FIG. 18, there is shown an example wherein the first TIM 9 is a PSH where a thermally conductive filler 13 stays as a liquid at service temperature and the polymeric matrix 12 gives mechanical adhesion between the IHS 8 and the electronic component 1 in accordance with an embodiment of the present disclosure. The thermally conductive filler 13 may include indium, gallium, gallium-indium alloy, gallium-indium-tin alloy, gallium-indium-tin-zinc alloy, cadmium, cadmium alloys, indium-lead alloy, indium-lead-silver alloy, mercury, mercury alloys, bismuth-tin alloy, and indium-tin-bismuth alloy. The compositions described herein may improve oxidation properties and reduce reactivity of the thermally conductive filler 13.

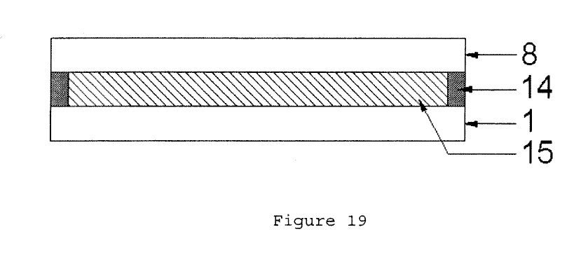

Referring to FIG. 19, there is shown an example wherein TIM material 15 may be placed directly between the IHS 8 and the electronic component 1 without the polymeric matrix 12 in accordance with an embodiment of the present disclosure. The TIM material 15 may be liquid metal such as gallium or low melting point metals or alloys. A confiner 14 may be used to prevent the TIM material 15 in liquid form from leaking out from between the IHS 8 and the electronic component 1. The compositions described herein may improve oxidation properties and reduce reactivity of the TIM material 15.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1-17. (canceled)

18. An electronic assembly, comprising:
a first electronic component;
a second electronic component; and
an interconnecting material connecting the first electronic component and the second electronic component; wherein the interconnecting material comprises an alloy composition or mixture consisting essentially of:
from about 90% to about 99.999% by weight indium or gallium, and
from about 0.001% to about 10% by weight of one or more of germanium, manganese, phosphorus, and titanium.

19. The electronic assembly of claim 18, wherein the alloy composition or mixture consists essentially of 90% to about 99.999% by weight indium and from about 0.001% to about 10% by weight of one or more of germanium, manganese, phosphorus, and titanium.

20. The electronic assembly of claim 18, wherein the alloy composition or mixture consists of 90% to about 99.999% by weight indium and from about 0.001% to about 10% by weight germanium.

21. The electronic assembly of claim 18, wherein the alloy composition or mixture consists essentially of 90% to about 99.999% by weight gallium and from about 0.001% to about 10% by weight of one or more of germanium, manganese, phosphorus, and titanium.

22. The electronic assembly of claim 18, wherein the alloy composition or mixture consists of 90% to about 99.999% by weight gallium and from about 0.001% to about 10% by weight germanium.

23. The electronic assembly of claim 18, wherein:
the first electronic component comprises an electronic device;
the second electronic component comprises an integrated heat spreader; and
the interconnecting material comprises a thermal interface material connecting the electronic device and the integrated heat spreader.

24. The electronic assembly of claim 23, wherein the interconnecting material further comprises one or more of a phase change material, a thermally conductive gel, a thermally conductive tape, and a thermal grease.

25. The electronic assembly of claim 23, wherein the interconnecting material further comprises a polymeric matrix containing the alloy composition or mixture.

26. The electronic assembly of claim 23, wherein the alloy composition or mixture is in a liquid state at service temperatures of the electronic assembly.

27. The electronic assembly of claim 23, wherein the alloy composition or mixture consists essentially of 90% to about 99.999% by weight gallium and from about 0.001% to about 10% by weight of one or one of germanium, manganese, phosphorus, and titanium.

28. The electronic assembly of claim 23, wherein the alloy composition or mixture consists of 90% to about 99.999% by weight gallium and from about 0.001% to about 10% by weight germanium.

29. The electronic assembly of claim 23, further comprising:
a heat sink; and
a second interconnecting material connecting the heatsink and the integrated heat spreader; wherein
the second interconnecting material comprises a second alloy composition or mixture consisting essentially of:
from about 90% to about 99999% by weight indium or gallium, and
from about 0.001% to about 10% by weight of one or more of germanium, manganese, phosphorus, and titanium.

30. The electronic assembly of claim 18, wherein:
the first electronic component comprises an electronic device;
the second electronic component comprises a substrate; and
the interconnecting material comprises a metallurgical interconnect connecting the electronic device and the substrate.

31. The electronic assembly of claim 30, wherein the alloy composition or mixture consists essentially of 90% to about 99.999% by weight indium and from about 0.001% to about 10% by weight of one or more of germanium, manganese, phosphorus, and titanium.

32. The electronic assembly of claim 30, wherein the alloy composition or mixture consists of 90% to about 99.999% by weight indium and from about 0.001% to about 10% by weight germanium.
